(19) United States
(12) Patent Application Publication
(10) Pub. No.: US 2026/0180234 A1
(43) Pub. Date: Jun. 25, 2026

(54) DEVICE AND METHOD FOR CONNECTING TWO PRINTED CIRCUIT BOARD PLUG CONNECTORS VIA A COUPLING ELEMENT

(71) Applicant: HARTING ELECTRIC STIFTUNG & CO. KG, Espelkamp (DE)

(72) Inventor: Torsten WOLF, Lübbecke (DE)

(21) Appl. No.: 19/121,403

(22) PCT Filed: Oct. 9, 2023
(86) PCT No.: PCT/DE2023/100748

§ 371 Date: Apr. 15, 2025

(30) Foreign Application Priority Data
Oct. 28, 2022 (DE) 10 2022 128 681.9

(51) Int. Cl. H01R 13/514; H01R 12/72

(52) U.S. Cl. CPC H01R 13/514; H01R 12/721; H05K 2201/10189

(57) ABSTRACT

Embodiments of the disclosure reduce the complexity required to mechanically connect at least two printed circuit board plug connectors together in a reversible manner. This is achieved by a device which has at least one introduction opening for introducing at least one coupling element in an introduction direction. The device additionally has at least two insertion openings for inserting at least two printed circuit board plug connectors in an insertion direction, wherein each of the two insertion openings is connected to the aforementioned introduction opening in order to allow a mechanical fixation of the coupling element to each of the two printed circuit board plug connectors.

### BACKGROUND

### Technical Field

The disclosure is directed to a device for reversibly mechanically connecting two printed circuit board plug connectors via a coupling element, and related methods.

Coupling elements are required to mechanically connect together in each case two printed circuit board plug connectors for joint mounting on a printed circuit board. The printed circuit board plug connectors are intended, on the one hand, to be connected with their plug contacts to traces of the printed circuit board and, on the other hand, to contact mating plug connectors with mating contacts at the plug-in side. The mating plug connectors can be printed circuit board mating plug connectors which are mounted on a further printed circuit board.

The printed circuit board plug connectors can in each case be composed of a plurality of individual printed circuit board plug connector modules and/or comprise the latter. The printed circuit board plug connector modules can for this purpose in each case be lined up on at least one connector and be fastened reversibly thereon.

### Description of the Related Art

The document DE 10 2019 109 471 A1 discloses an assembly consisting of a first modular printed circuit board plug connector and at least one second modular printed circuit board plug connector for joint mounting on a printed circuit board. The printed circuit board plug connectors are in each case composed of a plurality of individual plug connector modules. The plug connector modules are in each case lined up on at least one connector and are fastened reversibly thereon. The first printed circuit board plug connector and the second printed circuit board plug connector are reversibly connected to each other via a coupling element.

A disadvantage of this prior art is that the connection of two printed circuit board plug connectors via the coupling element is undesirably complex and requires manual dexterity because each of the two printed circuit board plug connectors has to be fastened manually to the coupling element, which generally requires precise positioning. Although possible, automatic connection by robots would accordingly then be extremely complex.

The German Patent and Trademark Office has conducted a search and found the following prior art in the priority application to the present application: DE 10 2017 119 287 A1, DE 10 2019 109 471 A1, DE 10 2019 125 797 A1, and DE 20 2004 007 857 U1.

### BRIEF SUMMARY

According to the present disclosure, a device is provided which is suited to reducing the complexity which is necessary to reversibly mechanically connect at least two printed circuit board plug connectors to each other via one or more coupling elements. A method with which it is possible to make the abovementioned connection by way of the abovementioned device is also provided.

A device serves to reversibly mechanically interconnect at least two printed circuit board plug connectors via at least one coupling element.

The device has at least one insertion opening for inserting the at least one coupling element in an insertion direction and moreover at least two plug-in openings for plugging in at least two printed circuit board plug connectors in a plug-in direction. The at least one insertion opening is thus connected to two of the plug-in openings in order to enable mechanical fixing of the at least one coupling element to in each case two of the printed circuit board plug connectors.

The connection of the printed circuit board plug connectors is significantly facilitated by way of this device.

Advantageously, two, but also more than two, printed circuit board plug connectors can be connected to each other such that they can be mounted on a printed circuit board much more simply than a plurality of individual printed circuit board plug connectors. In addition, each of the printed circuit board plug connectors can, as already mentioned, have a plurality of printed circuit board plug connector modules arranged in a row. The individual printed circuit board plug connector modules can have different functions and can be assembled individually. For example, for this purpose, a suitable mounting device for connecting the printed circuit board plug connector modules of a printed circuit board plug connector to a connecting element is also disclosed in DE 10 2019 125 797 A1. By virtue of the present disclosure, it is now also possible with very little effort to arrange these modules in a flat array by interconnecting a plurality of printed circuit board plug connectors (which can in each case have a plurality of modules), and thus to produce an array with rows and columns of plug connector modules with just minimal effort and to mount the latter on a printed circuit board as a compact unit, likewise with just minimal effort.

A particularly significant advantage consists in the increase in the degree of automatability. Lastly, it is, for example, much simpler, in particular for a robot, to plug printed circuit board plug connectors into plug-in openings provided for this purpose which can in particular also be provided with insertion slopes too, and to latch and/or clamp them with a coupling element fitted into the device in advance, than to perform this procedure exclusively manually—by hand or even with robot arms and corresponding sensors.

In an embodiment, the insertion direction and the plug-in direction can run at right angles to each other. This is particularly advantageous because the fastening, for example clamping or latching, to the coupling element is in this way designed very simply. For example, the latching devices and/or clamping devices can consequently be configured with very little effort on the respective coupling element and on the printed circuit board plug connectors.

In an preferred embodiment, the device has at least two insertion openings, namely at least one narrow insertion opening and at least one wide insertion opening. The at least one narrow insertion opening is configured to insert at least one narrow coupling element. It is arranged on a first side face of the device. The at least one wide insertion opening is configured to insert at least one wide coupling element and is arranged on a second side face of the device. The first and the second side face can be situated opposite each other.

The device can furthermore have at least four plug-in openings, namely, at least two narrow plug-in openings and at least two wide plug-in openings.

The wide plug-in openings are arranged on the first side face of the device and are connected to the narrow insertion opening. Each of the wide plug-in openings is configured for the plugging-in of a wide printed circuit board plug connector. The narrow plug-in openings are arranged at a second side face of the device and are connected to the wide insertion opening. Each of the narrow plug-in openings is configured for the plugging-in of a narrow printed circuit board plug connector.

In an advantageous development, the device has a baseplate. This is particularly advantageous because the device can be placed by way of this baseplate stably on a flat mounting apparatus such as, for example, a workbench, a desk, or the like.

The device can furthermore have a guide body which is built on the baseplate. The said first side face and the said second side face are then constituent parts of this guide body. The guide body can have an essentially cuboid basic shape. The first and the second side face can be constituent parts of this guide body. In particular, the first and the second side face can be situated opposite each other, and can be parallel to each other. This is particularly advantageous because the device in this way has a particularly compact structure. The cuboid basic shape has, on a side remote from the baseplate, a top face which may run parallel to the baseplate.

The plug-in openings, i.e., both the narrow and the wide plug-in openings, are open toward the top face. In addition, they can have insertion slopes at their openings in the top face. This enables and facilitates the plugging-in, in particular, the automated plugging-in, of the respective printed circuit board plug connectors.

In an embodiment, the two wide plug-in openings do not only face the top face but are additionally also open toward the first side face. This has the advantage of saving material and space and lower friction and better handling. The removal of the wide printed circuit board plug connectors, in particular, the wide printed circuit board plug connectors connected to each other, is also as a result facilitated or, depending on their form, made possible in the first place.

In a further advantageous embodiment, the narrow plug-in openings not only face the top face but in addition are also open toward the second side face. This has the advantage of saving material and space and lower friction and better handling. The removal of the narrow printed circuit board plug connectors, in particular, the narrow printed circuit board plug connectors connected to each other, is also as a result facilitated or, depending on their form, made possible in the first place.

The device may be configured to insert a narrow coupling element into the narrow insertion opening at the first side face. In particular, the device may be configured to plug in each case one wide printed circuit board plug connector into the, for example, two wide plug-in openings for the respective fastening to the narrow coupling element in order thus to mechanically connect these two wide printed circuit board plug connectors to each other via the narrow coupling element.

The device may be configured to insert a wide coupling element into the wide insertion opening at the second side face and to plug in each case one narrow printed circuit board plug connector into the, for example, two narrow plug-in openings for the respective fastening to the wide coupling element in order to mechanically connect these two narrow plug connectors to each other via the wide coupling element.

A method for reversibly mechanically interconnecting at least two printed circuit board plug connectors via at least one coupling element to form at least one printed circuit board plug connector pair by way of a device of the abovementioned type may have the following method steps:
A. inserting a wide coupling element into a wide insertion opening and/or a narrow coupling element into a narrow insertion opening of the device;
B. plugging two narrow printed circuit board plug connectors into in each case one of the two narrow plug-in openings and/or two wide printed circuit board plug connectors into in each case one of the two wide plug-in openings of the device;
C. jointly reversibly fastening, for example by latching or clamping, the two narrow printed circuit board plug connectors to the wide coupling element and consequently connecting them to form a narrow printed circuit board plug connector pair and/or jointly reversibly fastening, for example by latching or clamping, the two wide printed circuit board plug connectors to the narrow coupling element and consequently connecting them to form a wide printed circuit board plug connector pair; and
D. removing the narrow and/or wide printed circuit board plug connector pair from the respective narrow and/or wide plug-in opening.

The abovementioned removal in method step D can take place parallel to the baseplate.

In this way, the printed circuit board plug connectors can in each case be mechanically connected to each other at least on one side to form a plug connector pair.

In particular, the said narrow and wide printed circuit board plug connectors have an elongated basic shape with two narrow sides and two long sides. Although the narrow sides of the wide printed circuit board plug connector pair are wider than those of the narrow printed circuit board plug connectors, they are still significantly narrower than their long sides.

The narrow and the wide printed circuit board plug connectors can advantageously be plugged to each other. Accordingly, their lengths then also correspond. The narrow printed circuit board plug connectors can be plugged, for example geometrically, into the wide printed circuit board plug connectors. For example, the wide printed circuit board plug connectors can have (male) pin contacts and the narrow printed circuit board plug connectors can have (female) socket contacts. In particular, the wide printed circuit board plug connectors can have printed circuit board plug connector modules with (male) pin contacts and the narrow printed circuit board plug connectors have printed circuit board plug connector modules with (female) socket contacts. Because of their geometry, it is of course advantageous that the two wide printed circuit board plug connectors are connected to each other via the at least one narrow coupling element and the two narrow printed circuit board plug connectors are connected to each other via the at least one wide coupling element to form a corresponding printed circuit board plug connector pair.

In particular, the connection of more than two printed circuit board plug connectors to form an array is also possible by way of a device which has precisely two narrow and precisely two wide plug-in openings as well as precisely one wide and one narrow insertion opening. After removal, the already connected printed circuit board plug connector pair can finally be plugged into the device again, but shifted, such that one of the two printed circuit board plug connectors are connected again to a further printed circuit board plug connector via an additional coupling element. Three printed circuit board plug connectors are then already mechanically connected to one another. This procedure can of course be repeated until the desired array is ultimately created.

A device with more than one insertion opening and with more than two narrow and/or wide plug-in openings can furthermore also be provided, wherein the plug-in openings are in each case arranged on the first and/or second side face at equidistant distances from each other. Thus, although the material cost and the production cost of the device are increased, the complexity of the method in the case of the mechanical connection of whole arrays of printed circuit board plug connectors is reduced because in this way more than two printed circuit board plug connectors can also simultaneously be connected to one another. An optimum number of plug-in openings can thus be determined for a specific use case and a suitable device, in particular for automated connection, offered to a customer. An additive method, such as, for example, 3D printing, is appropriate for short production runs in order to meet individual customer requests. In contrast, an injection-molding process is also possible as a production method. For cost reasons, the device can generally in any case be made from plastic in order to exploit the advantage of inexpensive and simple production.

It is advantageous for manual operation if the device has a one-part design. It can, however, also make sense for the device to have a multi-part design, for example, if the connection is to be made automatically by a robot or the like, so that the different parts need to be arranged, locally separated, at suitable positions in the corresponding facility. In particular, the wide plug-in openings can then, together with the narrow insertion opening, belong to a first part of the device, and the narrow plug-in openings can, together with the wide insertion opening, belong to a second part of the device and be arranged independently of one another in the production facility for separate fitting.

According to the abovementioned method, the printed circuit board plug connectors of each printed circuit board plug connector pair are, however, first connected to each other only at in each case one narrow side. The printed circuit board plug connector pair already connected on one side (or the array) can, however, also be rotated by 180° and be replugged into the device provided beforehand with a further coupling element in order to mechanically connect to each other printed circuit board plug connectors of the printed circuit board plug connector pair in a comparable fashion at their other narrow side too.

In particular, the method can therefore additionally also have the following method steps:
E. inserting a further narrow coupling element into the narrow insertion opening and/or a further wide coupling element into the wide insertion opening of the device;
F. rotating the wide and/or narrow printed circuit board plug connector by 180°;
G. jointly plugging the wide and/or the narrow printed circuit board plug connector pair into the wide and/or narrow plug-in openings with the side remote from the coupling element already fastened to them foremost;
H. additionally mechanically interconnecting the two narrow and/or the two wide printed circuit board plug connectors via the respective further coupling element at their previously as yet unconnected side; and
I. jointly removing again the wide and/or the narrow printed circuit board plug connector pair from the narrow and/or wide plug-in openings of the device.

The abovementioned removal in method step I can take place parallel to the baseplate.

If, as described above, a whole array consisting of more than two printed circuit board plug connectors are to be connected to one another, these printed circuit board plug connectors can advantageously first be connected to one another in pairs at their first side/narrow side and then, when complete, be rotated by 180° and be connected to one another at their second side/narrow side.

### BRIEF DESCRIPTION OF THE SEVERAL VIEWS OF THE DRAWINGS

An example embodiment of the invention is illustrated in the drawings and explained in detail below. In the drawings:

FIGS. 1a, b show a device from two different viewpoints;

FIGS. 2a, b show the device with coupling elements inserted;

FIGS. 3a-c show the device with plugged-in printed circuit board plug connectors.

The figures may contain partially simplified schematic illustrations. Identical reference signs are in part used for the same but possibly non-identical elements. Different views of the same elements could be to a different scale. Specified directions such as, for example, “left,” “right,” “up,” and “down” are to be understood with reference to the respective figure and can vary in the individual illustrations with respect to the object illustrated.

### DETAILED DESCRIPTION

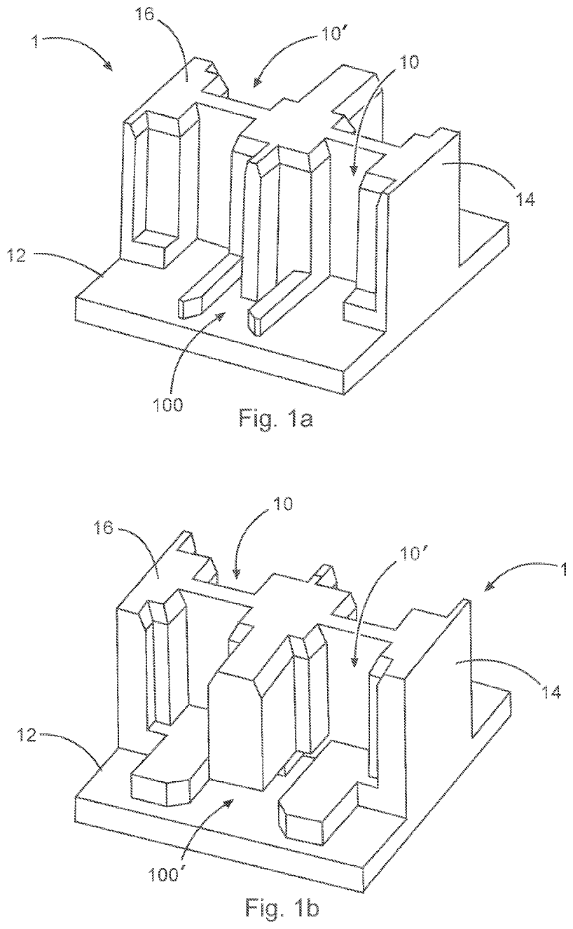

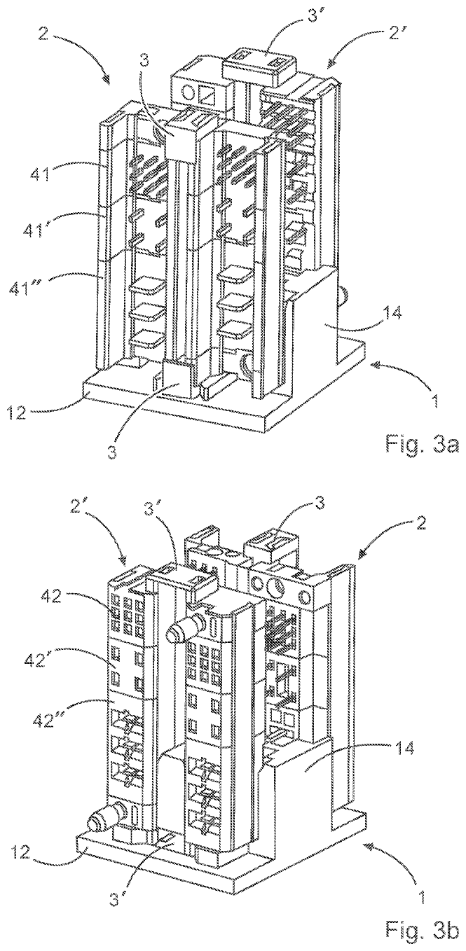

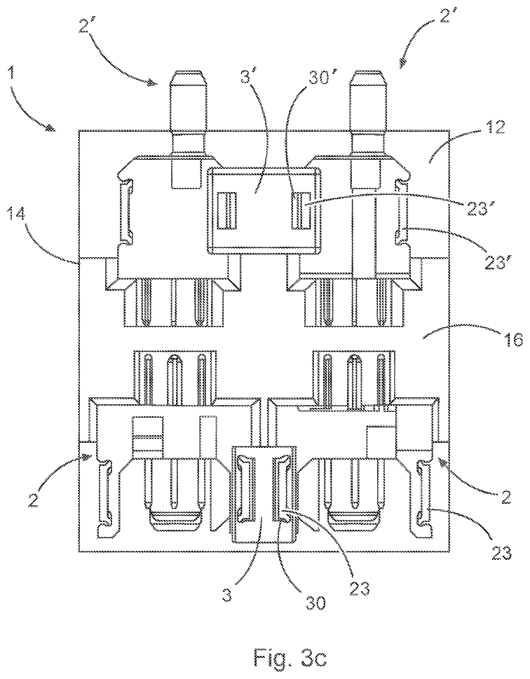

FIG. 1a and FIG. 1b show a device 1 for reversibly mechanically interconnecting two printed circuit board plug connectors 2, 2′ which are shown in FIGS. 3a-c. FIG. 1a shows the device with a view of a first side face of the device 1, and FIG. 1b with a view of a second side face of this device 1.

The device 1 is designed as a single piece and has a baseplate 12 and a guide body 14 built on the baseplate 12. The guide body 14 has an essentially cuboid basic shape in which on both sides, i.e., on the two opposite parallel side faces, in each case two, i.e., a total of four, plug-in openings 10, 10′ are arranged. Furthermore, arranged in the vicinity of the baseplate 12 on both sides are in each case one, i.e., a total of two, insertion openings 100, 100′. To be more precise, two wide plug-in openings 10 are arranged on the first side face and two narrow plug-in openings 10′ are arranged on the second side face. The first and the second side face are opposite side faces of the essentially cuboid guide body 14 and are not described in more detail for reasons of clarity. The guide body has a top face 16 situated opposite the baseplate. The plug-in openings 10, 10′ are open toward the respective side face on which they are arranged. In addition, the plug-in openings 10, 10′ are open toward the top face 16 and provided at this opening with insertion slopes.

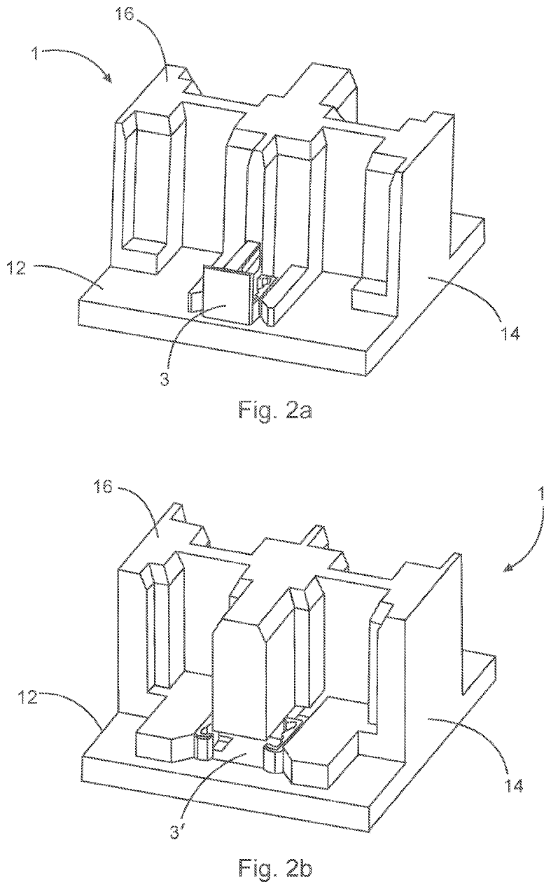

FIGS. 2a and 2b show the device 1 with coupling elements 3, 3′ inserted therein on both sides, namely, a narrow coupling element 3 and a wide coupling element 3′, with a view of the first and second side face respectively. It can easily be seen, in conjunction with the preceding illustration, that the coupling elements 3, 3′ are each arranged in one of the abovementioned insertion openings 100, 100′, namely, the narrow coupling element 3 in the narrow insertion opening 100 and the wide coupling element 3′ in the wide insertion opening 100′.

FIGS. 3a-c show the abovementioned assembly together with in each case two, i.e., a total of four, printed circuit board plug connectors 2, 2′ plugged into the respective plug-in openings 10, 10′ on both sides, namely, two wide printed circuit board plug connectors 2 and two narrow printed circuit board plug connectors 2′.

The two wide printed circuit board plug connectors 2 are arranged in the wide plug-in openings 10 of the device 1 and the two narrow printed circuit board plug connectors 2′ are arranged in the narrow plug-in openings 10′ of the device 1 by them having been plugged beforehand in each case into the respective plug-in openings 10, 10′, from above in the drawings. They are thus jointly connected to each other via the interposed coupling element 3, 3′ by them being clamped and/or latched at their ends in each case to the coupling element 3, 3′. Thereupon, they can be removed in particular parallel to the baseplate 12 of the device 1.

It is evident that the printed circuit board plug connectors 2, 2′ are each provided with a coupling element 3, 3′ not just at one narrow side but at two opposite narrow sides. For this purpose, they have been plugged beforehand individually into the associated plug-in openings 10, 10′ in order thus to be fastened to each other in each case via a first narrow or wide coupling element 3, 3′. They have then been rotated by 180° and replugged into the plug-in openings 10, 10′ in order additionally to be fastened to each other also at their second narrow side situated opposite the in each case first coupling element 3, 3′, already fastened thereon, via a further coupling element 3, 3′ which has been inserted into the respective insertion opening 100, 100′ in the meantime.

The printed circuit board plug connectors 2, 2′ can each have two latching and/or clamping lugs 23, 23′ shown in FIG. 3c for fastening purposes. The coupling elements 3, 3′ can each have a latching and/or clamping window 30, 30′ which thus interacts reversibly in a fastening fashion.

If it is desired to form an array consisting of more than two printed circuit board plug connectors 2, 2′, the two printed circuit board plug connectors 2, 2′, now in each case already connected to form a printed circuit board plug connector pair, can be shifted by one plug-in slot/plug-in recess 10, 10′ and reinserted into the device 1 and mechanically connected to a further printed circuit board plug connector 2, 2′ in the abovementioned fashion. This procedure can be repeated until an array of the desired size is created.

The wide printed circuit board plug connectors 2 are male plug connectors, i.e., they have, for example, pin contacts.

The wide printed circuit board plug connectors 2′ are female plug connectors, i.e., they have socket contacts.

Furthermore, the plug connectors are modular printed circuit board plug connectors 2, 2′, i.e., they have in each case a plurality of printed circuit board plug connector modules 41, 41′, 41′″, 42, 42′, 42″ arranged in each case in a row. The male printed circuit board plug connectors 2 have male printed circuit board plug connector modules 41, 41′, 41′″, and the female printed circuit board plug connectors 2′ have female printed circuit board plug connector modules 42, 42′, 42″.

The male printed circuit board plug connectors 2 are constructed so that they correspond to the female printed circuit board plug connectors 2′ and can be plugged to them. Both printed circuit board plug connector pairs and whole arrays of individually and comfortably assemblable plug-connector modules can thus be assembled in a particularly comfortable fashion on two printed circuit boards in the form of printed circuit board plug connectors and printed circuit board mating plug connectors in order to electrically connect the printed circuit boards.

Aspects of the various embodiments described above can be combined to provide further embodiments. In general, in the following claims, the terms used should not be construed to limit the claims to the specific embodiments disclosed in the specification and the claims, but should be construed to include all possible embodiments along with the full scope of equivalents to which such claims are entitled.

1. A device for reversibly mechanically interconnecting at least two printed circuit board plug connectors via at least one coupling element, wherein the device has at least one insertion opening for inserting the at least one coupling element in an insertion direction and wherein the device furthermore has at least two plug-in openings for plugging in the at least two printed circuit board plug connectors in a plug-in direction, wherein the at least one insertion opening is connected to two of the plug-in openings in order to enable mechanical fixing of the at least one coupling element to two of the printed circuit board plug connectors.

2. The device as claimed in claim 1, wherein the insertion direction and the plug-in direction run at right angles to each other.

3. The device as claimed in claim 1, wherein the device has a one-part design.

4. The device as claimed in claim 1, wherein the device has a multi-part design.

5. The device as claimed in claim 1, wherein the device is made from plastic.

6. The device as claimed in claim 5, wherein the device is produced in an additive manufacturing method.

7. The device as claimed in claim 5, wherein the device is produced in an injection-molding method.

8. The device as claimed in claim 1, wherein the device has at least two insertion openings, namely at least one narrow insertion opening which is configured to insert a narrow coupling element and is arranged on a first side face of the device, and at least one wide insertion opening which is configured to insert a wide coupling element and is arranged on a second side face of the device.

9. The device as claimed in claim 8, wherein the device has at least four plug-in openings, namely at least two narrow plug-in openings which are arranged on the first side face and are connected to the at least one narrow insertion opening, and at least two narrow plug-in openings which are arranged on the second side face and are connected to the at least one narrow insertion opening.

10. The device as claimed in claim 9, wherein the device has a baseplate and a guide body, wherein the guide body is built on the baseplate, and wherein the said first side face and the said second side face are constituent parts of the guide body.

11. The device as claimed in claim 10, wherein the guide body has an essentially cuboid basic shape.

12. The device as claimed in claim 10, wherein the plug-in openings are open toward a top face, remote from the baseplate, of the guide body.

13. The device as claimed in claim 12, wherein the plug-in openings have insertion slopes in a region adjacent the top face.

14. The device as claimed in claim 9, wherein the device is configured to insert a narrow coupling element into the narrow insertion opening at the first side face and to insert a wide coupling element into the wide insertion opening at the second side face, and wherein the device is further configured to plug one respective wide printed circuit board plug connector into the two wide plug-in openings for the joint fastening to the narrow coupling element in order thus to mechanically reversibly connect the two wide printed circuit board plug connectors to each other via the narrow coupling element, and to plug one respective narrow printed circuit board plug connector into the two narrow plug-in openings for the joint fastening to the wide coupling element in order to mechanically reversibly connect the two narrow plug connectors to each other.

15. A method for reversibly mechanically interconnecting at least two printed circuit board plug connectors via at least one coupling element to form at least one printed circuit board plug connector pair by way of a device, the method comprising:
inserting a narrow coupling element into a narrow insertion opening of the device and/or a wide coupling element into a wide insertion opening of the device;
plugging two wide printed circuit board plug connectors into in each case one of two wide plug-in openings of the device and/or two narrow printed circuit board plug connectors into in each case one of two narrow plug-in openings of the device;
jointly reversibly fastening the two wide printed circuit board plug connectors to the narrow coupling element and consequently connecting them to form a wide printed circuit board plug connector pair and/or jointly reversibly fastening the two narrow printed circuit board plug connectors to the wide coupling element and consequently connecting them to form a wide printed circuit board plug connector pair; and
removing the wide and/or narrow printed circuit board plug connector pair from the respective wide and/or narrow plug-in opening.

16. The method as claimed in claim 15, further comprising:
inserting a further narrow coupling element into the narrow insertion opening and/or a further wide coupling element into the wide insertion opening of the device;
rotating the wide and/or narrow printed circuit board plug connector by 180°;
plugging the wide and/or the narrow printed circuit board plug connector pair into the wide and/or narrow plug-in openings with a side remote from the coupling element already latched to them foremost;
mechanically interconnecting again the two wide and/or the two narrow printed circuit board plug connectors via a respective further narrow and/or wide coupling element at a previously as yet unconnected side; and
jointly removing again the wide printed circuit board plug connector pair, now connected on both sides, and/or the narrow printed circuit board plug connector pair, now connected on both sides, from the wide and/or narrow plug-in openings of the device.
